(19) United States
(12) Patent Application Publication
(10) Pub. No.: US 2025/0199369 A1
(43) Pub. Date: Jun. 19, 2025

(54) DISPLAY DEVICE

(71) Applicant: Japan Display Inc., Tokyo (JP)

(72) Inventor: Shuji HAYASHI, Tokyo (JP)

(21) Appl. No.: 18/975,233

(22) Filed: Dec. 10, 2024

(30) Foreign Application Priority Data
Dec. 14, 2023 (JP) 2023-211522

(51) Int. Cl. G02F 1/1362; G02F 1/1368; H10K 59/80

(52) U.S. Cl. CPC G02F 1/136209; G02F 1/1368; H10K 59/8792

(57) ABSTRACT

According to an aspect, a display device includes a display panel that has a display area in which a plurality of pixels are arranged in a first direction and a second direction intersecting the first direction and is configured to allow a mirror image of an image viewed in plan view from one side of the display area to be viewed from another side. At least a partial area of the display area includes: a plurality of first areas each of which is visible from the one side and has a surface on the other side configured to be shielded from light; and a plurality of second areas each of which is visible from the other side and has a surface on the one side configured to be shielded from light.

### CROSS-REFERENCE TO RELATED APPLICATION

This application claims the benefit of priority from Japanese Patent Application No. 2023-211522 filed on Dec. 14, 2023, the entire contents of which are incorporated herein by reference.

### BACKGROUND

### 1. Technical Field

What is disclosed herein relates to a display device.

### 2. Description of the Related Art

There has been disclosed a display device configured to allow a viewer to see, from one surface side of a display panel, a background on the other surface side thereof. The display device is what is called a see-through display and includes a display panel that includes a liquid crystal layer containing polymer-dispersed liquid crystals, and a light source located so as to face a side surface of the display panel. There has been disclosed a see-through display configured as a self-luminous organic electroluminescent (EL) display device in which an interlayer insulating film and a planarization film in a display area are removed.

In a see-through display, an image seen from one surface side is a mirror image of an image seen from the other surface side. Consequently, to ensure the legibility of textual information included in an image for both the image seen from the one surface side and the image seen from the other surface side, twice the size of a display area is required. If, alternatively, the display area of the textual information is reduced, for example, by reducing the font size, the legibility of the text may be reduced.

For the foregoing reasons, there is a need for a display device capable of increasing the legibility of the text.

### SUMMARY

According to an aspect, a display device includes a display panel that has a display area in which a plurality of pixels are arranged in a first direction and a second direction intersecting the first direction and is configured to allow a mirror image of an image viewed in plan view from one side of the display area to be viewed from another side. At least a partial area of the display area includes: a plurality of first areas each of which is visible from the one side and has a surface on the other side configured to be shielded from light; and a plurality of second areas each of which is visible from the other side and has a surface on the one side configured to be shielded from light.

### BRIEF DESCRIPTION OF THE DRAWINGS

FIG. 1 is a block diagram illustrating a schematic configuration of a display device according to an embodiment of the present disclosure;

FIG. 2 is a schematic sectional view of a display panel;

FIG. 3 is a timing diagram illustrating sub-frame periods and light emission periods in a one-frame period during which display image data is displayed;

FIG. 4A is a conceptual diagram illustrating an exemplary display aspect according to a comparative example;

FIG. 4B is a conceptual diagram illustrating another exemplary display aspect according to the comparative example;

FIG. 5A is a conceptual diagram illustrating an exemplary textual-information display area according to the embodiment;

FIG. 5B is a conceptual diagram illustrating another exemplary textual-information display area according to the embodiment;

FIG. 6A is a conceptual diagram illustrating an exemplary display aspect in the textual-information display area according to the embodiment;

FIG. 6B is a conceptual diagram illustrating another exemplary display aspect in the textual-information display area according to the embodiment;

FIG. 7A is an enlarged view of the textual-information display area according to a first embodiment of the present disclosure;

FIG. 7B is an enlarged view of the textual-information display area according to the first embodiment;

FIG. 7C is a sectional arrow view taken along line A-A illustrated in FIGS. 7A and 7B;

FIG. 7D is a sectional arrow view taken along line B-B illustrated in FIGS. 7A and 7B;

FIG. 8A is an enlarged view of the textual-information display area according to a first modification of the first embodiment;

FIG. 8B is an enlarged view of the textual-information display area according to the first modification of the first embodiment;

FIG. 8C is a sectional arrow view taken along line B-B illustrated in FIGS. 8A and 8B;

FIG. 9A is an enlarged view of the textual-information display area according to a second modification of the first embodiment;

FIG. 9B is an enlarged view of the textual-information display area according to the second modification of the first embodiment;

FIG. 9C is a sectional arrow view taken along line A-A illustrated in FIGS. 9A and 9B;

FIG. 10A is an enlarged view of the textual-information display area according to a second embodiment of the present disclosure;

FIG. 10B is an enlarged view of the textual-information display area according to the second embodiment;

FIG. 10C is a sectional arrow view taken along line A-A illustrated in FIGS. 10A and 10B;

FIG. 10D is a sectional arrow view taken along line B-B illustrated in FIGS. 10A and 10B;

FIG. 11A is an enlarged view of the textual-information display area according to a first modification of the second embodiment;

FIG. 11B is an enlarged view of the textual-information display area according to the first modification of the second embodiment;

FIG. 11C is a sectional arrow view taken along line B-B illustrated in FIGS. 11A and 11B;

FIG. 12A is an enlarged view of the textual-information display area according to a second modification of the second embodiment;

FIG. 12B is an enlarged view of the textual-information display area according to the second modification of the second embodiment;

FIG. 12C is a sectional arrow view taken along line A-A illustrated in FIGS. 12A and 12B;

FIG. 13A is an enlarged view of the textual-information display area according to a third embodiment of the present disclosure;

FIG. 13B is an enlarged view of the textual-information display area according to the third embodiment;

FIG. 13C is a sectional arrow view taken along line A-A illustrated in FIGS. 13A and 13B;

FIG. 13D is a sectional arrow view taken along line B-B illustrated in FIGS. 13A and 13B;

FIG. 14A is an enlarged view of the textual-information display area according to a first modification of the third embodiment;

FIG. 14B is an enlarged view of the textual-information display area according to the first modification of the third embodiment;

FIG. 14C is a sectional arrow view taken along line B-B illustrated in FIGS. 14A and 14B;

FIG. 15A is an enlarged view of the textual-information display area according to a second modification of the third embodiment;

FIG. 15B is an enlarged view of the textual-information display area according to the second modification of the third embodiment;

FIG. 15C is a sectional arrow view taken along line A-A illustrated in FIGS. 15A and 15B;

FIG. 16A is an enlarged view of the textual-information display area according to a fourth embodiment of the present disclosure;

FIG. 16B is an enlarged view of the textual-information display area according to the fourth embodiment;

FIG. 17A is an enlarged view of the textual-information display area according to a first modification of the fourth embodiment;

FIG. 17B is an enlarged view of the textual-information display area according to the first modification of the fourth embodiment;

FIG. 18A is an enlarged view of the textual-information display area according to a second modification of the fourth embodiment; and

FIG. 18B is an enlarged view of the textual-information display area according to the second modification of the fourth embodiment.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the disclosure. To further clarify the description, the drawings schematically illustrate, for example, widths, thicknesses, and shapes of various parts as compared with actual aspects thereof, in some cases. However, they are merely examples, and interpretation of the present disclosure is not limited thereto. The same element as that illustrated in a drawing that has already been discussed is denoted by the same reference numeral through the description and the drawings, and detailed description thereof will not be repeated in some cases where appropriate.

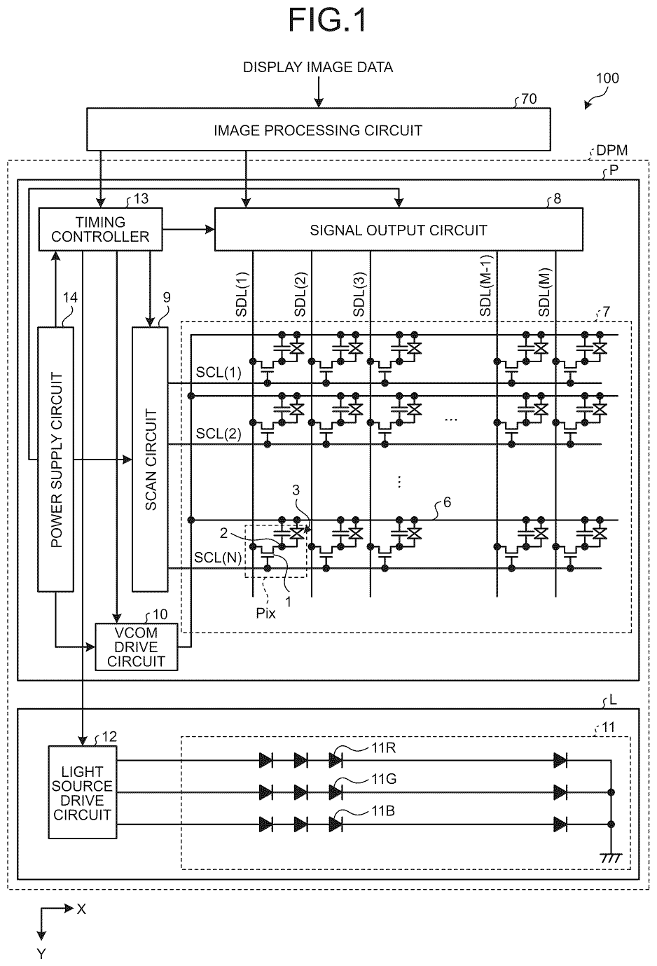

FIG. 1 is a block diagram illustrating a schematic configuration of a display device according to an embodiment of the present disclosure. In the present disclosure, a display device 100 is a transmissive liquid crystal display device that performs display output using what is called a field-sequential color (FSC) system to control pixels so that light in a plurality of colors is transmitted through the same pixels at times different from one another.

As illustrated in FIG. 1, the display device 100 according to the embodiment includes a display panel module DPM and an image processing circuit 70. The display panel module DPM includes a display panel P and a light source device L.

The display panel P includes a display area 7, a signal output circuit 8, a scan circuit 9, a VCOM drive circuit 10, a timing controller 13, and a power supply circuit 14. Hereafter, one surface of the display panel P as the display area 7 is viewed in plan view from one side is referred to as a “first surface”, and the other surface on which a mirror image of an image displayed on the first surface is visible is referred to as a “second surface”. A lateral side of the display device 100 refers to a side located, with respect to the display device 100, in a direction intersecting (at, for example, a right angle) a direction in which the first surface faces the second surface.

A plurality of pixels Pix are arranged in a matrix having a row-column configuration in an X direction (first direction) and a Y direction (second direction) in the display area 7. The Y direction (second direction) is a direction intersecting the X direction (first direction). More specifically, in the example illustrated in FIG. 1, the Y direction (second direction) is a direction orthogonal to the X direction (first direction).

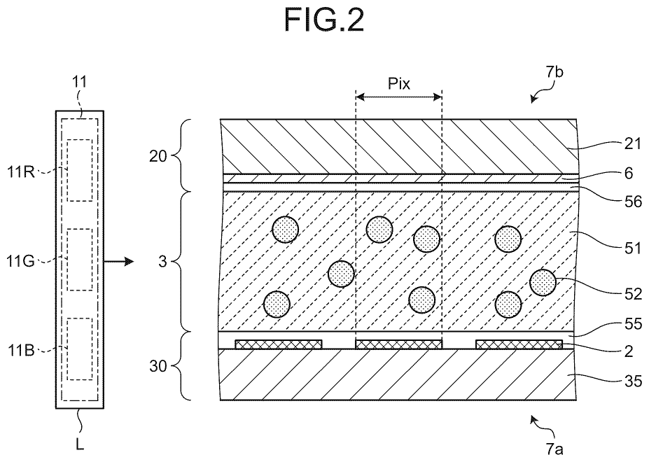

Each of the pixels Pix includes a switching element 1 and two electrodes. FIG. 2 is a schematic sectional view of the display panel. FIGS. 1 and 2 illustrate a pixel electrode 2 and a common electrode 6 as two electrodes.

The display panel P includes two substrates facing each other and liquid crystals 3 enclosed between the two substrates. Hereinafter, one of the two substrates is referred to as a first substrate 30, and the other of them is referred to as a second substrate 20. In the present disclosure, a surface on the first substrate 30 side of the display panel P is referred to as a first surface 7a, and a surface on the second substrate 20 side of the display panel P is referred to as a second surface 7b.

The first substrate 30 includes a light-transmitting glass substrate 35, the pixel electrode 2 stacked on the second substrate 20 side of the glass substrate 35, and an insulating layer 55 stacked on the second substrate 20 side so as to cover the pixel electrode 2. The pixel electrode 2 is individually provided for each of the pixels Pix. The second substrate 20 includes a light-transmitting glass substrate 21, the common electrode 6 stacked on the first substrate 30 side of the glass substrate 21, and an insulating layer 56 stacked on the first substrate 30 side of the common electrode 6 so as to cover the common electrode 6. The common electrode 6 has a plate-like or film-like shape shared among the pixels Pix.

The liquid crystals 3 of the first embodiment are polymer-dispersed liquid crystals (PDLCs). In other words, in the present embodiment, the display panel P is a liquid crystal panel in which the polymer-dispersed liquid crystals are enclosed. Specifically, the liquid crystals 3 includes a bulk 51 and fine particles 52. The fine particles 52 change in orientation in the bulk 51 in accordance with a potential difference between the pixel electrode 2 and the common electrode 6. By individually controlling the potential of the pixel electrode 2 for each of the pixels Pix, the scattering state of the liquid crystals 3 is controlled for each of the pixels Pix.

FIG. 2 illustrates an example in which the pixel electrode 2 and the common electrode 6 are arranged so as to face each other with the liquid crystals 3 interposed therebetween. However, the display panel P may be configured such that the pixel electrode 2 and the common electrode 6 are provided on one substrate, and an electric field generated by the pixel electrode 2 and the common electrode 6 changes the orientation of the liquid crystals 3 and thus controls the scattering state of the liquid crystals 3.

The following describes a mechanism for controlling the potentials of the pixel electrode 2 and the common electrode 6.

The switching element 1 is a switching element using a semiconductor such as a thin-film transistor (TFT). One of the source and the drain of the switching element 1 is coupled to one of the two electrodes (pixel electrode 2). The other of the source and the drain of the switching element 1 is coupled to a signal line SDL (m) (m is an integer in a range from 1 to M, where M is a total number of the signal lines). The gate of the switching element 1 is coupled to a scan line SCL (n) (n is an integer in a range from 1 to N, where N is a total number of the scan lines). Under the control of the scan circuit 9, the scan line SCL (n) applies a potential to open or close a circuit between the source and the drain of the switching element 1. The scan circuit 9 controls the potential.

In the example illustrated in FIG. 1, a plurality of the signal lines SDL (n) are arranged along one of the arrangement directions (row direction) of the pixels Pix. The signal line SDL (m) extends along the other of the arrangement directions (column direction) of the pixels Pix. The signal line SDL (m) is shared by the switching elements 1 of the pixels Pix arranged in the column direction. A plurality of the scan lines SCL (n) are arranged along the column direction. The scan line SCL (n) extends along the row direction. The scan line SCL (n) is shared by the switching elements 1 of the pixels Pix arranged in the row direction.

In the present disclosure, the X direction (first direction) refers to the direction in which the scan line SCL (n) extends, and the Y direction (second direction) refers to the direction in which the scan lines SCL (n) are arranged.

The common electrode 6 is coupled to the VCOM drive circuit 10. The VCOM drive circuit 10 applies a common potential to the common electrode 6.

The scan circuit 9 sequentially supplies a drive signal that serves as an ON potential (drive potential) of the switching elements 1 to the scan line SCL (n) coupled to the pixels Pix arranged in the X direction (first direction). In other words, the scan circuit 9 simultaneously supplies the drive signal to the pixels Pix arranged in the X direction (first direction). The scan circuit 9 sequentially supplies the drive signal to the pixels Pix arranged in the Y direction (second direction).

The signal output circuit 8 sequentially supplies, to the signal line SDL (m) coupled to the pixels Pix arranged in the Y direction (second direction), pixel signals that serves as pixel data corresponding to the pixels Pix. In other words, the signal output circuit 8 sequentially supplies the pixel data to the pixels Pix arranged in the Y direction (second direction). The signal output circuit 8 simultaneously supplies the pixel data to the pixels Pix arranged in the X direction (first direction).

When the scan circuit 9 supplies the drive signal to the scan line SCL (n) and the switching elements 1 of the pixels Pix arranged in the X direction (first direction) are controlled to be turned on, the signal output circuit 8 outputs the pixel signals to the signal lines SDL (m) to charge the liquid crystals 3 (fine particles 52) serving as a storage capacitor and a capacitive load provided between the pixel electrodes 2 of the pixels Pix arranged in the X direction (first direction) and the common electrode 6. As a result, a voltage corresponding to the pixel data of each of the pixels Pix arranged in the X direction (first direction) is applied between the pixel electrode 2 of the pixel Pix and the common electrode 6. The scan circuit 9 sequentially supplies the drive signal to the scan lines SCL (n) arranged in the Y direction (second direction), and the signal output circuit 8 supplies the pixel data corresponding to the pixels Pix coupled to the scan lines SCL (n) supplied with the drive signals by the scan circuit 9. As a result, the pixel data of an image for one sub-frame (one of a plurality of monochromatic images constituting an image for one frame) is written.

After the switching element 1 is turned off, the voltage applied between pixel electrode 2 and the common electrode 6 is held by the liquid crystals 3 (fine particles 52) serving as the storage capacitor and the capacitive load. The degree of scattering of the liquid crystals 3 (fine particles 52) is controlled according to the voltage applied between the pixel electrode 2 of each of the pixels Pix and the common electrode 6. For example, the liquid crystal 3 may be polymer-dispersed liquid crystals that increase the degree of scattering with the increase in voltage applied between the pixel electrode 2 of each of the pixels Pix and the common electrode 6, or may be polymer-dispersed liquid crystals that increase the degree of scattering with the decrease in voltage applied between the pixel electrode 2 of each of the pixels Pix and the common electrode 6.

As illustrated in FIG. 2, the light source device L is located on a lateral side of the display panel P (lower side of the display panel P in FIG. 1). The light source device L includes a light source 11 that emits light to a side surface of the display panel P and a light source drive circuit 12 that controls the light source 11. The light source 11 includes a first light source 11R, a second light source 11G, and a third light source 11B.

The first light source 11R, the second light source 11G, and the third light source 11B each emit light under the control of the light source drive circuit 12. The first light source 11R, the second light source 11G, and the third light source 11B are light sources using light-emitting elements such as light-emitting diodes (LEDs), but are not limited to such light sources, and only need to be light sources controllable in light emission timing.

The light source drive circuit 12 controls the light emission timing of the first light source 11R, the second light source 11G, and the third light source 11B under the control of the timing controller 13. In the present disclosure, the emission color of the first light source 11R (first color) is red (R), the emission color of the second light source 11G (second color) is green (G), and the emission color of the third light source 11B (third color) is blue (B).

When the light is emitted from the light source 11, the display area 7 is irradiated by the light (first color, second color, and third color) emitted from one side surface side in the Y direction. Each of the pixels Pix transmits or scatters the light emitted from the one side surface side in the Y direction. The degree of scattering of the liquid crystals 3 for each of the pixels Pix depends on the state of the liquid crystals 3 controlled according to the pixel signal for each of the pixels Pix.

The timing controller 13 is a circuit that controls the operation timing of the signal output circuit 8, the scan circuit 9, the VCOM drive circuit 10, and the light source drive circuit 12. In the present disclosure, the timing controller 13 operates based on signals received via the image processing circuit 70.

The image processing circuit 70 outputs signals based on display image data to the signal output circuit 8 and the timing controller 13. When the pixel data is assumed to be data indicating red-green-blue (RGB) gradation values assigned to one of the pixels Pix provided in the display area 7, the display image data supplied to the image processing circuit 70 to output an image for display is a set of a plurality of pieces of the pixel data for the respective pixels Pix in the display area 7. The image processing circuit 70 may be provided on one of the substrates included in the display panel P, may be mounted on a flexible printed circuit board provided with, for example, wiring extending from the display panel P, or may be provided outside the display panel P.

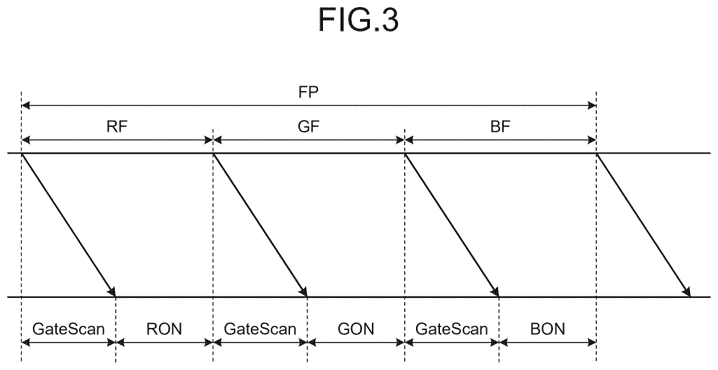

FIG. 3 is a timing diagram illustrating sub-frame periods and light emission periods in a one-frame period during which the display image data is displayed. In FIG. 3, an image display period FP for one frame is set to 20 ms. In this case, the image display frame rate of the display device 100 is set to 50 frames per second (fps).

In the display device 100 that performs the display output using the FSC system, the image display period FP for one frame based on the display image data is divided into a first sub-frame period RF, a second sub-frame period GF, and a third sub-frame period BF, as illustrated in FIG. 3. The first sub-frame period RF, the second sub-frame period GF, and the third sub-frame period BF are each set to 6.67 ms.

During a vertical scan period GateScan (first period) of the first sub-frame period RF, the pixel data corresponding to an output gradation value of each of the pixels Pix corresponding to the first color (red (R)) of the display image data is written. As a result, a voltage corresponding to the pixel data for each of the pixels Pix is applied to the pixel electrode 2 of the pixel Pix, and the scattering state of the liquid crystals 3 for each of the pixels Pix is controlled according to the voltage applied to the pixel electrode 2 of the pixel Pix. The vertical scan period GateScan (first period) of the first sub-frame period RF is set to 2.5 ms, for example.

The first light source 11R emits light during a subsequent light emission period RON (second period). During this light emission period RON (second period), light in the first color (red (R)) corresponding to the pixel data for each of the pixels Pix written in the previous vertical scan period GateScan is scattered and displayed.

During the vertical scan period GateScan (first period) of the second sub-frame period GF, the pixel data corresponding to an output gradation value of each of the pixels Pix corresponding to the second color (green (G)) of the display image data is written. As a result, a voltage corresponding to the pixel data for each of the pixels Pix is applied to the pixel electrode 2 of the pixel Pix, and the scattering state of the liquid crystals 3 for each of the pixels Pix is controlled according to the voltage applied to the pixel electrode 2 of the pixel Pix. The vertical scan period GateScan (first period) of the second sub-frame period GF is set to 2.5 ms, for example.

The second light source 11G emits light during a subsequent light emission period GON (second period). During this light emission period GON (second period), light in the second color (green (G)) corresponding to the pixel data for each of the pixels Pix written in the previous vertical scan period GateScan is scattered and displayed.

During the vertical scan period GateScan (first period) of the third sub-frame period BF, the pixel data corresponding to an output gradation value of each of the pixels Pix corresponding to the third color (blue (B)) of the display image data is written. As a result, a voltage corresponding to the pixel data for each of the pixels Pix is applied to the pixel electrode 2 of the pixel Pix, and the scattering state of the liquid crystals 3 for each of the pixels Pix is controlled according to the voltage applied to the pixel electrode 2 of the pixel Pix. The vertical scan period GateScan (first period) of the third sub-frame period BF is set to 2.5 ms, for example.

The third light source 11B emits light during a subsequent light emission period BON (second period). During this light emission period BON (second period), light in the third color (blue (B)) corresponding to the pixel data for each of the pixels Pix written in the previous vertical scan period GateScan is scattered and displayed.

In the display device 100 based on the FSC system described above, an image in which three colors of the first color (red (R)), the second color (green (G)), and the third color (blue (B)) are combined (mixed) is recognized because of the afterimage phenomenon due to temporal limitation of human eye resolution. Since the display device 100 based on the FSC system does not require a color filter for each of the pixels Pix, light transmittance in the display area 7 can be made higher.

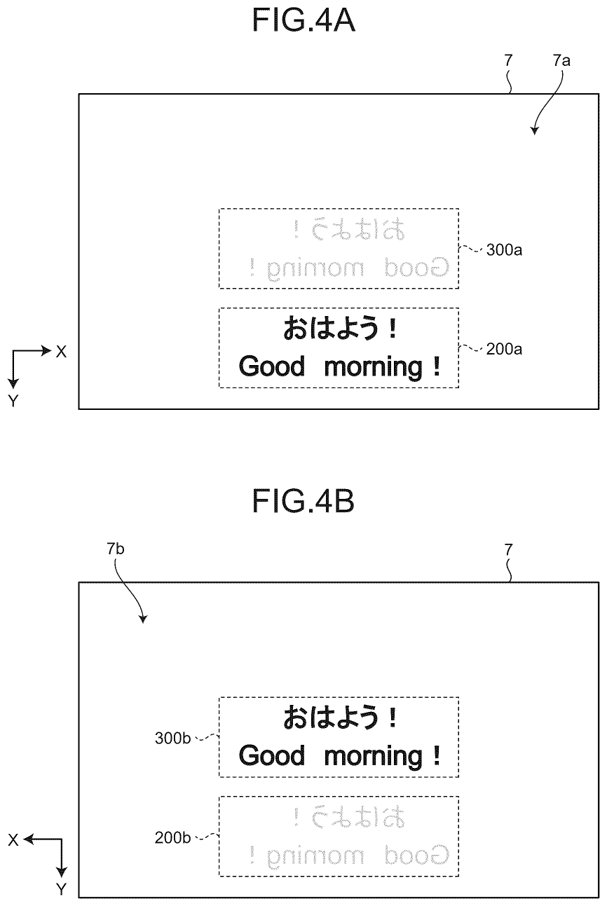

FIGS. 4A and 4B are conceptual diagrams illustrating exemplary display aspects according to a comparative example.

As described above, the display panel P is configured to allow the mirror image of the image viewed in plan view from one side of the display area 7 to be viewed from the other side. In other words, the image displayed on the first surface 7a of the display panel P as the display area 7 is viewed in plan view from the one side and the image displayed on the second surface 7b of the display panel P as the display area 7 is viewed in plan view from the other side are mirror images of each other.

FIG. 4A illustrates a display example on the first surface 7a of the display panel P as the display area 7 is viewed in plan view from the one side. FIG. 4B illustrates a display example on the second surface 7b of the display panel P as the display area 7 is viewed in plan view from the other side. These figures illustrate aspects in which the display panel P displays: first textual information 200a that is legible when the first surface 7a of the display panel P is viewed in plan view from the one side; and second textual information 300b that is legible when the second surface 7b of the display panel P is viewed in plan view from the other side.

The first textual information 200a is visible as first textual information 200b that is reversed as a mirror image when the second surface 7b of the display panel P is viewed in plan view from the other side. The second textual information 300b is visible as second textual information 300a that is reversed as a mirror image when the second surface 7b of the display panel P is viewed in plan view from the other side. Thus, in the display aspects illustrated in the comparative example, twice the size of the display area is required to ensure legibility of the textual information both when the first surface 7a of the display panel P is viewed from the one side and when the second surface 7b of the display panel P is viewed from the other side. If, alternatively, the display area of the textual information is reduced, for example, by reducing the font size, the legibility of the text may be reduced.

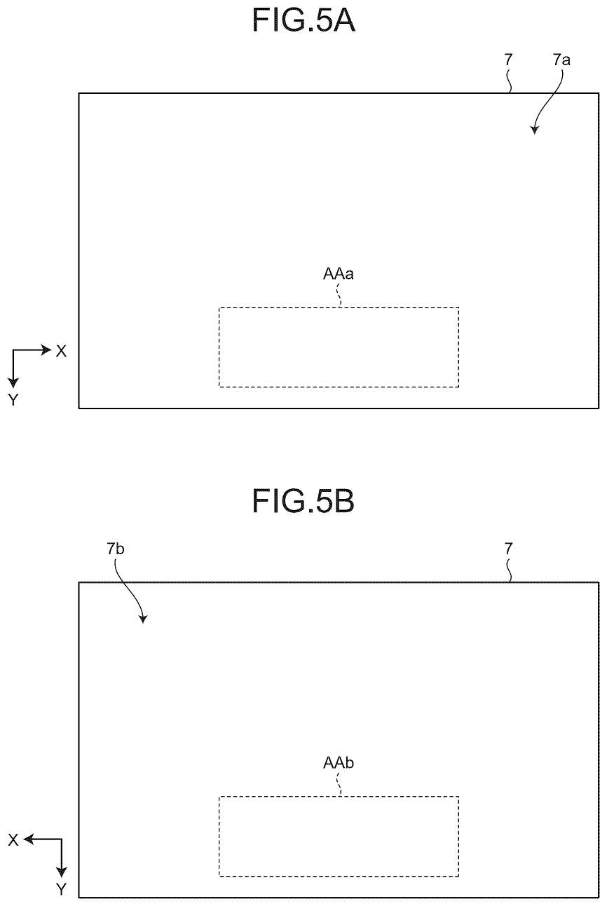

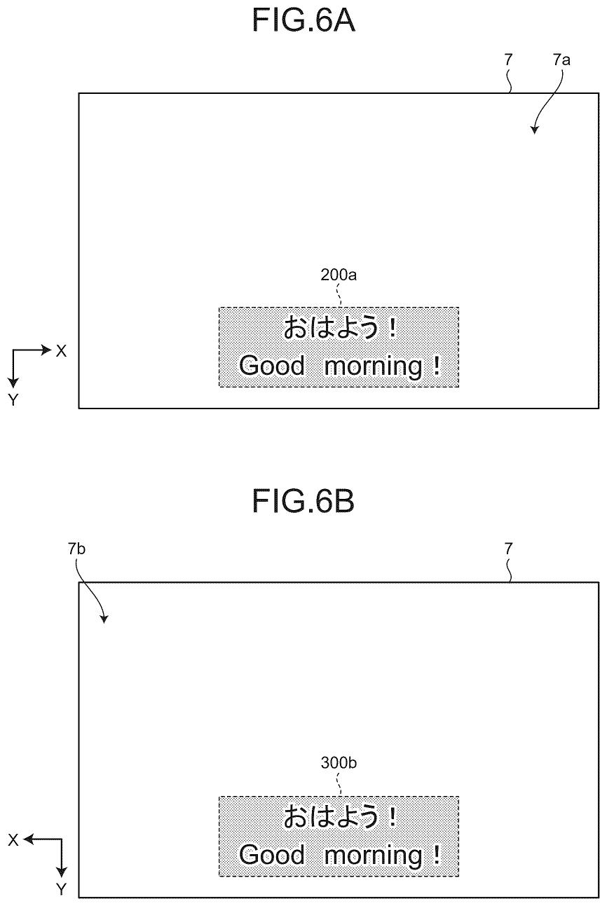

FIGS. 5A and 5B are conceptual diagrams illustrating exemplary textual-information display areas according to the embodiment. FIGS. 6A and 6B are conceptual diagrams illustrating exemplary display aspects in the textual-information display areas according to the embodiment.

FIG. 5A illustrates a textual-information display area AAa on the first surface 7a of the display panel P as the display area 7 is viewed in plan view from the one side. FIG. 5B illustrates a textual-information display area AAb on the second surface 7b of the display panel P as the display area 7 is viewed in plan view from the other side.

FIG. 6A illustrates a display example of the first textual information 200a in the textual-information display area AAa. FIG. 6B illustrates a display example of the second textual information 300b in the textual-information display area AAb.

In the present embodiment, as illustrated in FIGS. 6A and 6B, the first textual information 200a that is legible when the first surface 7a of the display panel P is viewed in plan view from the one side is displayed in the textual-information display area AAa illustrated in FIG. 5A, and the second textual information 300b that is legible when the second surface 7b of the display panel P is viewed in plan view from the other side is displayed in the textual-information display area AAb illustrated in FIG. 5B.

In the present embodiment, the textual-information display area AAa and the textual-information display area AAb are respectively provided on the first surface 7a and the second surface 7b of the display panel P serving as front and back sides of the same area, and the mirror image (corresponding to 200b illustrated in FIG. 4B) of the first textual information 200a displayed in the textual-information display area AAa when the first surface 7a of the display panel P is viewed in plan view from the one side is not visible when the second surface 7b of the display panel P is viewed in plan view from the other side. The mirror image (corresponding to 300a illustrated in FIG. 4A) of the second textual information 300b displayed in the character information display area AAb when the second surface 7b of the display panel P is viewed in plan view from the other side is not visible when the first surface 7a of the display panel P is viewed in plan view from the one side.

The following describes configurations that can achieve the display aspects according to the embodiment described above.

### 1. First Embodiment

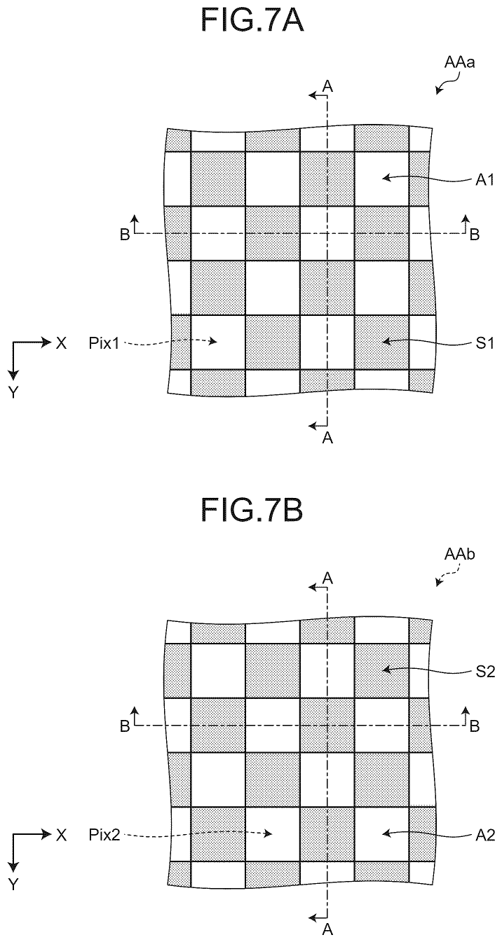

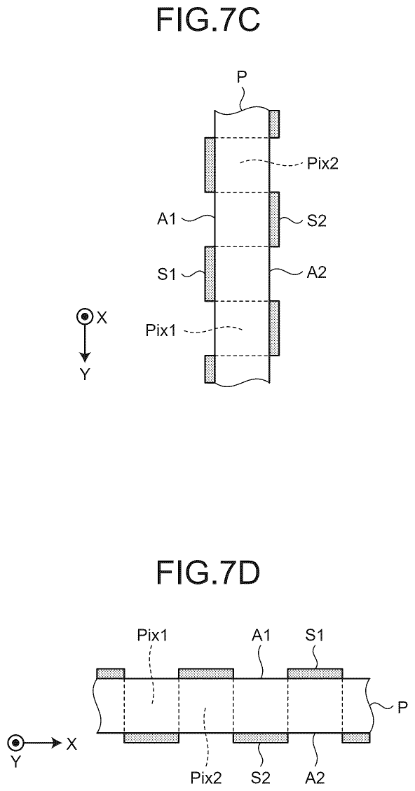

FIGS. 7A and 7B are enlarged views of the textual-information display areas according to a first embodiment of the present disclosure. FIG. 7C is a sectional arrow view taken along line A-A illustrated in FIGS. 7A and 7B. FIG. 7D is a sectional arrow view taken along line B-B illustrated in FIGS. 7A and 7B.

FIG. 7A illustrates a first light-blocking pattern when the textual-information display area AAa is viewed in plan view from the one side. FIG. 7B illustrates a second light-blocking pattern when the textual-information display area AAb is viewed transparently from the one side.

The textual-information display areas AA (AAa and AAb) include a plurality of first areas A1 and a plurality of second areas A2. The second surface 7b side of each first area A1 is shielded by a first light-blocking pattern S1 and visible from the one side, and the first surface 7a side of each second area A2 is shielded by a second light-blocking pattern S2 and visible from the other side.

In the configuration according to the first embodiment, the first areas A1 are provided, each corresponding to one pixel Pix1. The second areas A2 are provided, each corresponding to one pixel Pix2.

In the configuration according to the first embodiment, the first areas A1 and the second areas A2 are provided so as to be alternately arranged in the X direction (first direction). The first areas A1 and the second areas A2 are provided so as to be also alternately arranged in the Y direction (second direction). As a result, the first light-blocking pattern S1 and the second light-blocking pattern S2 each form a checkered light-blocking pattern on a pixel basis.

The first light-blocking pattern S1 may be, for example, formed by applying a black resin material to a surface of the second substrate 20, or formed on a transparent base member different from the second substrate 20 and bonded to the surface of the second substrate 20 side of the display panel P. Alternatively, the first light-blocking pattern S1 may be provided on the common electrode 6.

The second light-blocking pattern S2 may be, for example, formed by applying a black resin material to a surface of the first substrate 30, or formed on a transparent base member different from the first substrate 30 and bonded to the surface of the first substrate 30 side of the display panel P. Alternatively, the second light-blocking pattern S2 may be provided on the pixel electrodes 2.

The first light-blocking pattern S1 and the second light-blocking pattern S2 are not limited to the resin paint. The first light-blocking pattern S1 and the second light-blocking pattern S2 may, for example, be formed by a light-blocking metal material.

In the configuration described above, the image processing circuit 70 performs image processing so that the first textual information 200a is visible when the first surface 7a of the display panel P is viewed in plan view from the one side, and the second textual information 300b is visible when the second surface 7b of the display panel P is viewed in plan view from the other side.

In other words, the pixels Pix2 corresponding to the second textual information 300a that is the mirror image of the second textual information 300b are masked by the first light-blocking pattern when the first surface 7a of the display panel P is viewed in plan view from the one side, and the image displayed in the textual-information display area AAa when the first surface 7a of the display panel P is viewed in plan view from the one side is visible as the first textual information 200a formed by the pixels Pix1 corresponding to the first areas A1.

The pixels Pix1 corresponding to the first textual information 200b that is the mirror image of the first textual information 200a are masked by the second light-blocking pattern when the second surface 7b of the display panel P is viewed in plan view from the other side, and the image displayed in the textual-information display area AAb when the second surface 7b of the display panel P is viewed in plan view from the other side is visible as the second textual information 300b formed by the pixels Pix2 corresponding to the second areas A2.

As a result, both when the first surface 7a of the display panel P is viewed from the one side and when the second surface 7b of the display panel P is viewed from the other side, the legibility can be ensured while optimizing the display area and the font size of the textual information. Since no mirror image text is visible, the visibility of the entire image can be enhanced.

### First Modification

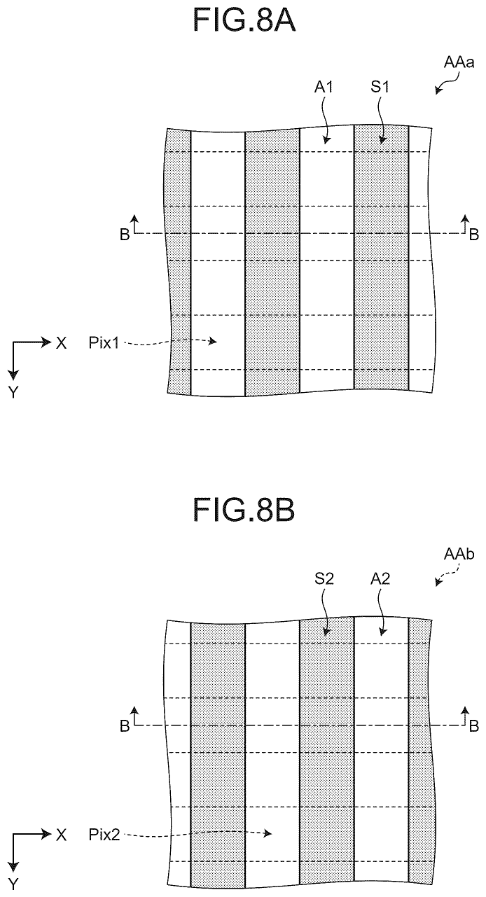

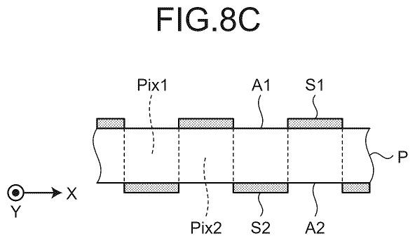

FIGS. 8A and 8B are enlarged views of the textual-information display areas according to a first modification of the first embodiment. FIG. 8C is a sectional arrow view taken along line B-B illustrated in FIGS. 8A and 8B. The same description as that in the first embodiment may be omitted.

In the configuration according to the first modification of the first embodiment, the first areas A1 are each provided correspondingly to one pixel column in which the pixels Pix1 are arranged in the Y direction (second direction). The second areas A2 are each provided correspondingly to one pixel column in which the pixels Pix2 are arranged in the Y direction (second direction).

In the configuration according to the first modification of the first embodiment, the first areas A1 and the second areas A2 are provided so as to be alternately arranged in the X direction (first direction). As a result, the first light-blocking pattern S1 and the second light-blocking pattern S2 form a vertical striped light-blocking pattern on a pixel column basis.

As a result, in the same way as in the first embodiment, both when the first surface 7a of the display panel P is viewed from the one side and when the second surface 7b of the display panel P is viewed from the other side, the legibility can be ensured while optimizing the display area and the font size of the textual information. Since no mirror image text is visible, the visibility of the entire image can be enhanced.

### Second Modification

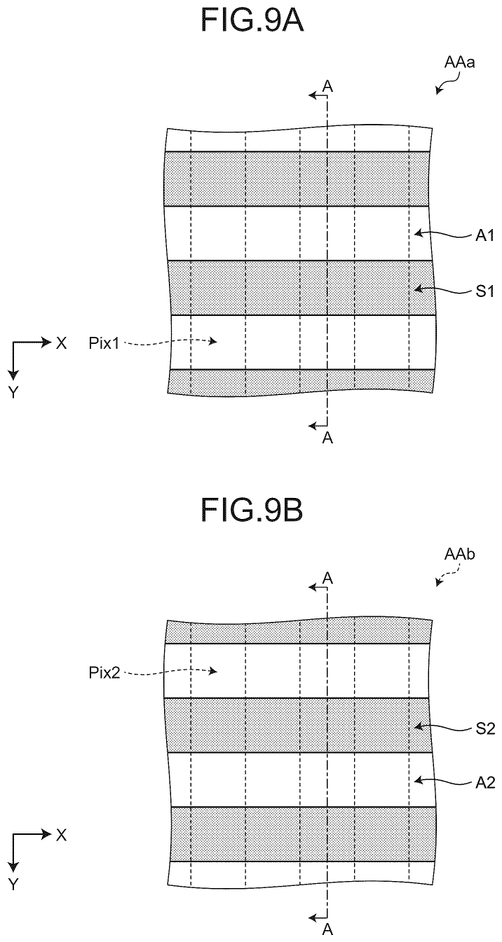

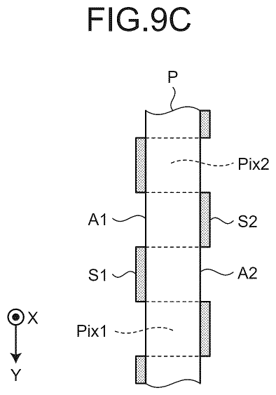

FIGS. 9A and 9B are enlarged views of the textual-information display areas according to a second modification of the first embodiment. FIG. 9C is a sectional arrow view taken along line A-A illustrated in FIGS. 9A and 9B. The same description as that in the first embodiment may be omitted.

In the configuration according to the second modification of the first embodiment, the first areas A1 are each provided correspondingly to one pixel row in which the pixels Pix1 are arranged in the X direction (first direction). The second areas A2 are each provided correspondingly to one pixel row in which the pixels Pix2 are arranged in the X direction (first direction).

In the configuration according to the second modification of the first embodiment, the first areas A1 and the second areas A2 are provided so as to be alternately arranged in the Y direction (second direction). As a result, the first light-blocking pattern S1 and the second light-blocking pattern S2 form a horizontally striped light-blocking pattern on a pixel row basis.

As a result, in the same way as in the first embodiment, both when the first surface 7a of the display panel P is viewed from the one side and when the second surface 7b of the display panel P is viewed from the other side, the legibility can be ensured while optimizing the display area and the font size of the textual information. Since no mirror image text is visible, the visibility of the entire image can be enhanced.

### 2. Second Embodiment

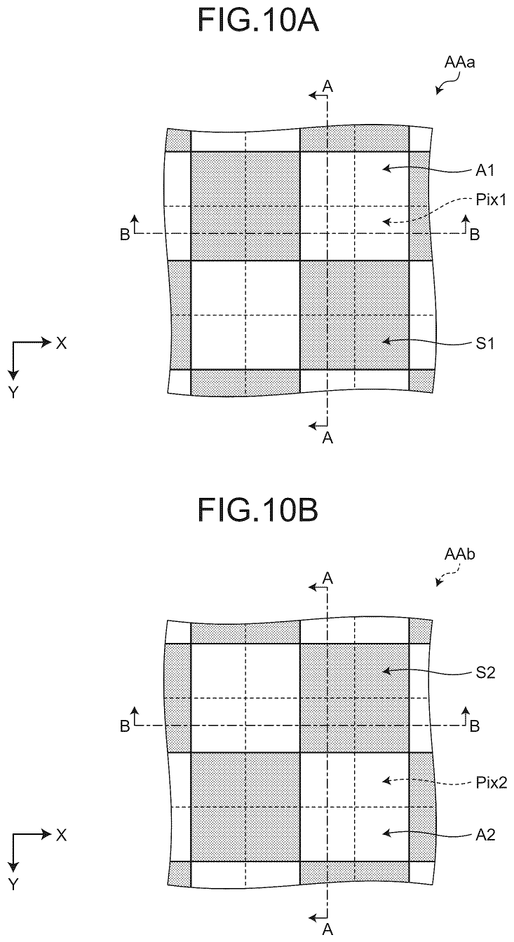

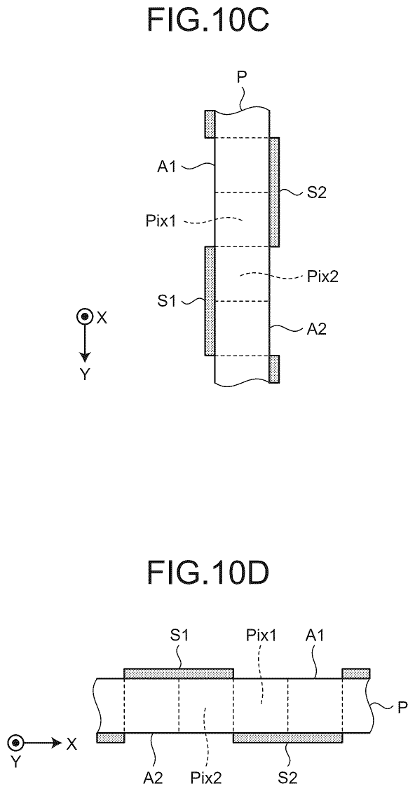

FIGS. 10A and 10B are enlarged views of the textual-information display areas according to a second embodiment of the present disclosure. FIG. 10C is a sectional arrow view taken along line A-A illustrated in FIGS. 10A and 10B. FIG. 10D is a sectional arrow view taken along line B-B illustrated in FIGS. 10A and 10B. The same description as that in the first embodiment may be omitted.

In the configuration according to the second embodiment, the first areas A1 are each provided correspondingly to more than one of the pixels Pix1. The second areas A2 are each provided correspondingly to more than one of the pixels Pix2.

In other words, the first areas A1 each include more than one of the pixels Pix1 in the X direction (first direction). The second areas A2 each include more than one of the pixels Pix2 in the X direction (first direction). This embodiment exemplifies an aspect in which the first areas A1 each include two of the pixels Pix1 in the X direction (first direction) and the second areas A2 each include two of the pixels Pix2 in the X direction (first direction).

The first areas A1 each include also more than one of the pixels Pix1 in the Y direction (second direction). The second areas A2 each include more than one of the pixels Pix2 in the Y direction (second direction). This embodiment exemplifies an aspect in which the first areas A1 each include two of the pixels Pix1 in the Y direction (second direction) and the second areas A2 each include two of the pixels Pix2 in the Y direction (second direction).

In the configuration according to the second embodiment, the first areas A1 and the second areas A2 are provided so as to be alternately arranged in the X direction (first direction). The first areas A1 and the second areas A2 are provided so as to be also alternately arranged in the Y direction (second direction). As a result, the first light-blocking pattern S1 and the second light-blocking pattern S2 each form a checkered light-blocking pattern on a plurality of (in this case, 2×2=4) pixels basis.

As a result, in the same way as in the first embodiment, both when the first surface 7a of the display panel P is viewed from the one side and when the second surface 7b of the display panel P is viewed from the other side, the legibility can be ensured while optimizing the display area and the font size of the textual information. Since no mirror image text is visible, the visibility of the entire image can be enhanced.

### First Modification

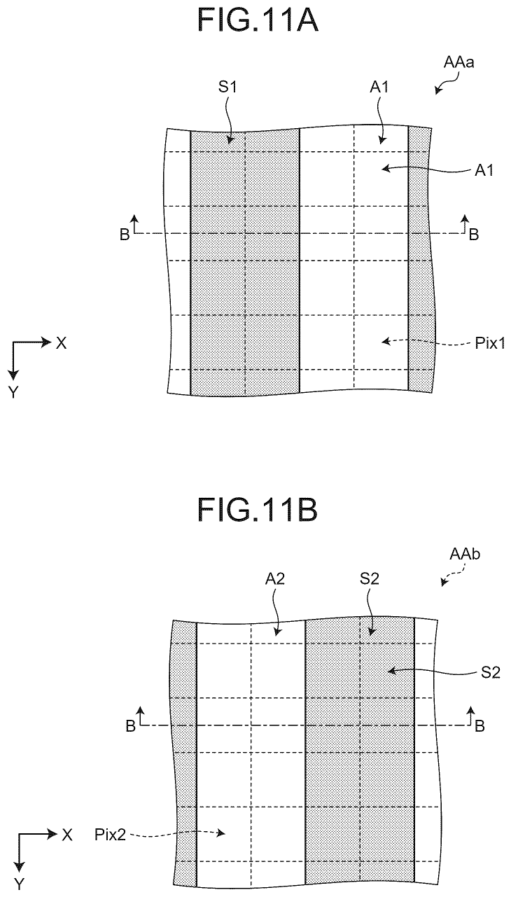

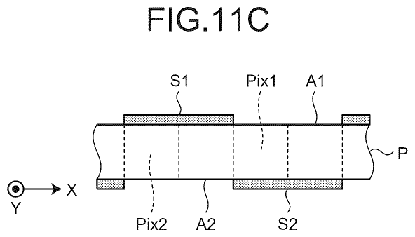

FIGS. 11A and 11B are enlarged views of the textual-information display areas according to a first modification of the second embodiment. FIG. 11C is a sectional arrow view taken along line B-B illustrated in FIGS. 11A and 11B. The same description as that in the first embodiment may be omitted.

In the configuration according to the first modification of the second embodiment, the first areas A1 are each provided correspondingly to a plurality of pixel columns in each of which the pixels Pix1 are arranged in the Y direction (second direction). The second areas A2 are each provided correspondingly to a plurality of pixel columns in each of which the pixels Pix2 are arranged in the Y direction (second direction). In other words, the first areas A1 and the second areas A2 each include a plurality of pixel columns arranged in the X direction (first direction). This modification exemplifies an aspect in which the first areas A1 and the second areas A2 each include two pixel columns arranged in the X direction (first direction).

In the configuration according to the first modification of the second embodiment, the first areas A1 and the second areas A2 are provided so as to be alternately arranged in the X direction (first direction). As a result, the first light-blocking pattern S1 and the second light-blocking pattern S2 each form a vertical stripe-shaped light-blocking pattern on a plurality of (in this case, 2) pixel columns basis.

As a result, in the same way as in the first embodiment, both when the first surface 7a of the display panel P is viewed from the one side and when the second surface 7b of the display panel P is viewed from the other side, the legibility can be ensured while optimizing the display area and the font size of the textual information. Since no mirror image text is visible, the visibility of the entire image can be enhanced.

### Second Modification

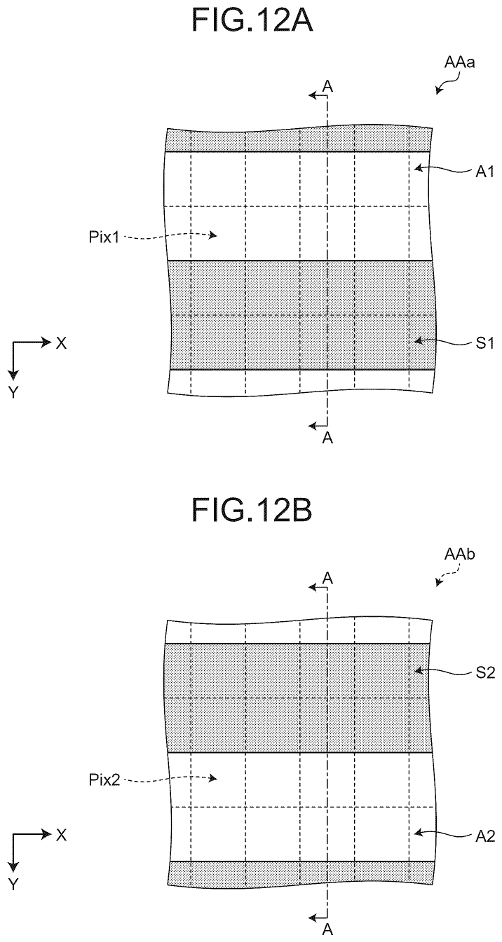

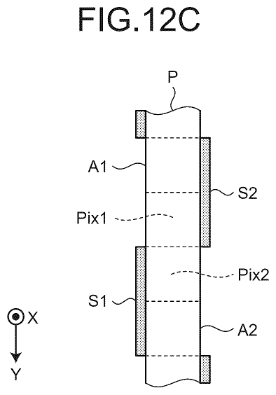

FIGS. 12A and 12B are enlarged views of the textual-information display areas according to a second modification of the second embodiment. FIG. 12C is a sectional arrow view taken along line A-A illustrated in FIGS. 12A and 12B. The same description as that in the first embodiment may be omitted.

In the configuration according to the second modification of the second embodiment, the first areas A1 are each provided correspondingly to a plurality of pixel rows in each of which the pixels Pix1 are arranged in the X direction (first direction). The second areas A2 are each provided correspondingly to a plurality of pixel rows in each of which the pixels Pix2 are arranged in the X direction (first direction). In other words, the first areas A1 and the second areas A2 each include a plurality of pixel rows arranged in the Y direction (second direction). This modification exemplifies an aspect in which the first areas A1 and the second areas A2 each include two pixel rows arranged in the Y direction (second direction).

In the configuration according to the second modification of the second embodiment, the first areas A1 and the second areas A2 are provided so as to be alternately arranged in the Y direction (second direction). As a result, the first light-blocking pattern S1 and the second light-blocking pattern S2 each form a horizontal stripe-shaped light-blocking pattern on a plurality of (in this case, 2) pixel rows basis.

As a result, in the same way as in the first embodiment, both when the first surface 7a of the display panel P is viewed from the one side and when the second surface 7b of the display panel P is viewed from the other side, the legibility can be ensured while optimizing the display area and the font size of the textual information. Since no mirror image text is visible, the visibility of the entire image can be enhanced.

### 3. Third Embodiment

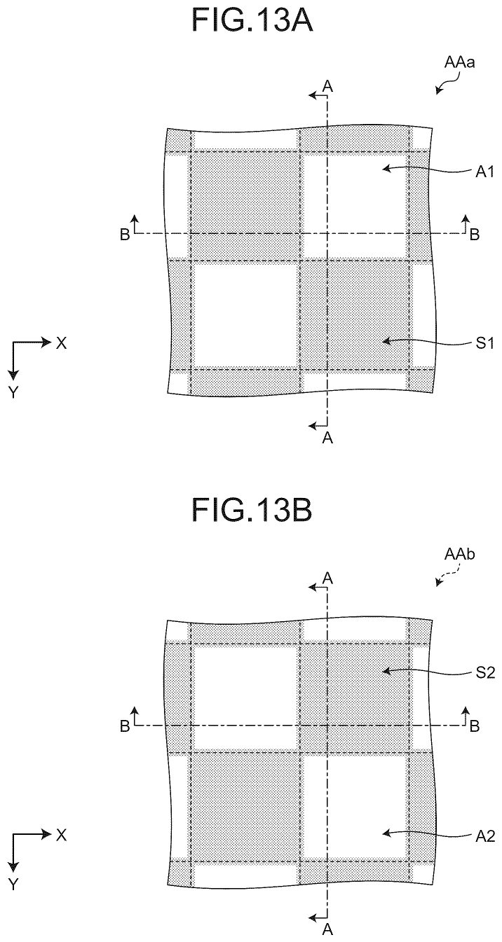

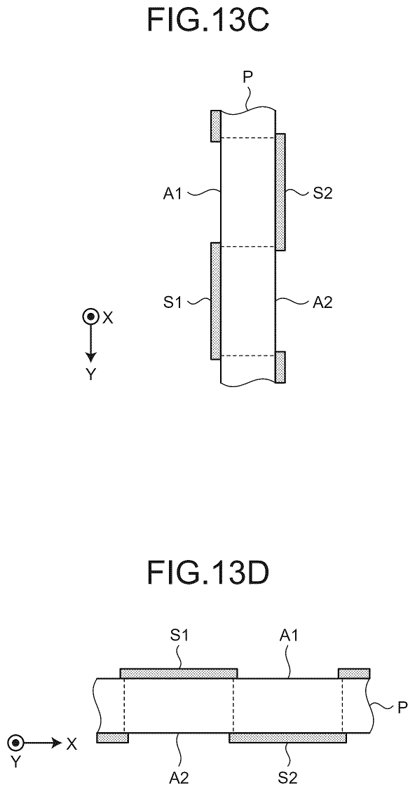

FIGS. 13A and 13B are enlarged views of the textual-information display areas according to a third embodiment of the present disclosure. FIG. 13C is a sectional arrow view taken along line A-A illustrated in FIGS. 13A and 13B. FIG. 13D is a sectional arrow view taken along line B-B illustrated in FIGS. 13A and 13B. The same description as that in the first embodiment may be omitted.

In the configuration according to the third embodiment, the first areas A1 are each provided correspondingly to one or more of the pixels. The second areas A2 are also each provided correspondingly to one or more of the pixels. In other words, the first areas A1 and the second areas A2 each include one or more of the pixels in the X direction (first direction). The first areas A1 and the second areas A2 each include also one or more of the pixels in the Y direction (second direction).

In the configuration according to the third embodiment, the first areas A1 and the second areas A2 are provided so as to be alternately arranged in the X direction (first direction). The first areas A1 and the second areas A2 are provided so as to be also alternately arranged in the Y direction (second direction). As a result, the first light-blocking pattern S1 and the second light-blocking pattern S2 each form a checkered light-blocking pattern on one or more of the pixels basis.

As illustrated in FIGS. 13A, 13B, 13C, and 13D, in the configuration according to the third embodiment, the first light-blocking patterns S1 overlap the second light-blocking patterns S2 in predetermined areas including boundary lines between the first areas A1 and the second areas A2 indicated by dashed lines in plan view. This configuration can reduce light leakage in the second areas A2 when the first surface 7a of the display panel P is viewed from the one side. Light leakage in the first areas A1 can also be reduced when the second surface 7b of the display panel P is viewed from the other side.

### First Modification

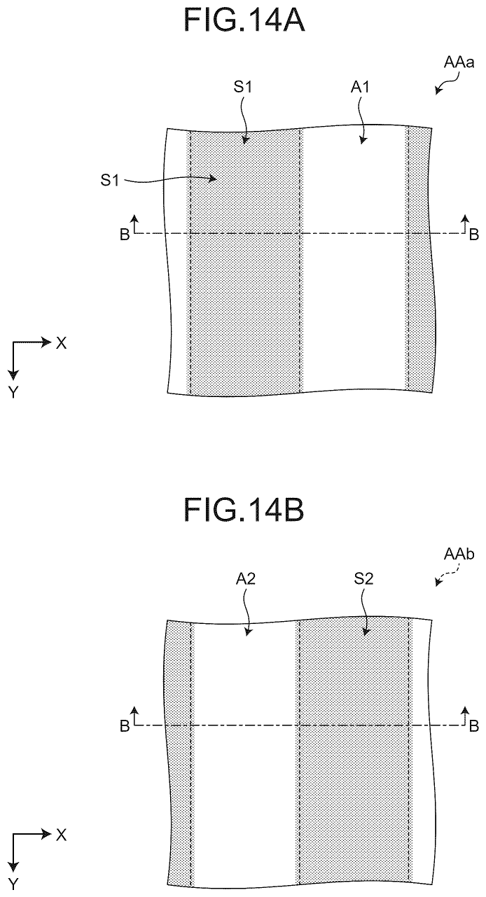

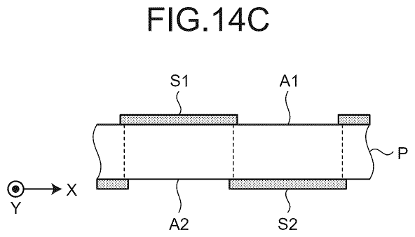

FIGS. 14A and 14B are enlarged views of the textual-information display areas according to a first modification of the third embodiment. FIG. 14C is a sectional arrow view taken along line B-B illustrated in FIGS. 14A and 14B. The same description as that in the first embodiment may be omitted.

In the configuration according to the first modification of the third embodiment, the first areas A1 are each provided correspondingly to one or more pixel columns in each of which the pixels Pix1 are arranged in the Y direction (second direction). The second areas A2 are each provided correspondingly to one or more pixel columns in each of which the pixels Pix2 are arranged in the Y direction (second direction). In other words, the first areas A1 and the second areas A2 each include one or more pixel columns arranged in the X direction (first direction).

In the configuration according to the first modification of the third embodiment, the first areas A1 and the second areas A2 are provided so as to be alternately arranged in the X direction (first direction). As a result, the first light-blocking pattern S1 and the second light-blocking pattern S2 each form a vertical stripe-shaped light-blocking pattern on one or more pixel columns basis.

As illustrated in FIGS. 14A, 14B, and 14C, in the configuration according to the first modification of the third embodiment, the first light-blocking patterns S1 overlap the second light-blocking patterns S2 in predetermined areas including boundary lines between the first areas A1 and the second areas A2 indicated by dashed lines in plan view. In the same way as in the third embodiment, this configuration can reduce the light leakage in the second areas A2 when the first surface 7a of the display panel P is viewed from the one side. The light leakage in the first areas A1 can also be reduced when the second surface 7b of the display panel P is viewed from the other side.

### Second Modification

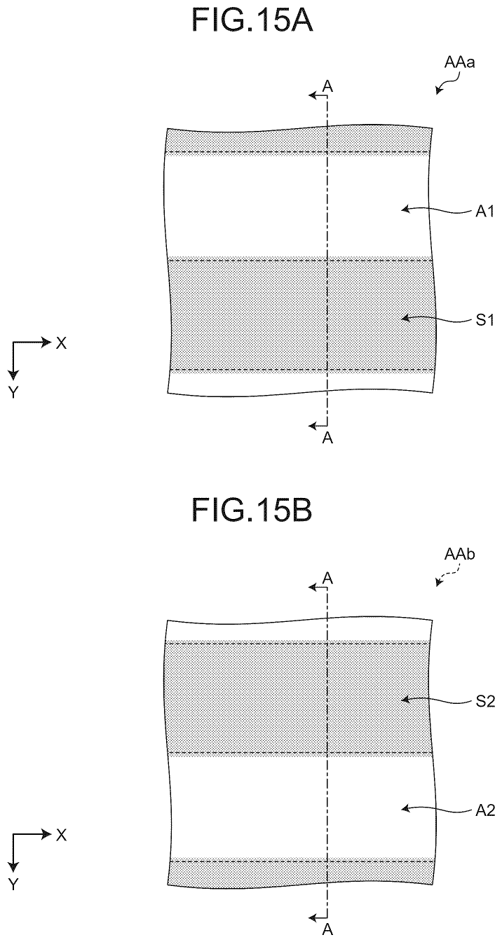

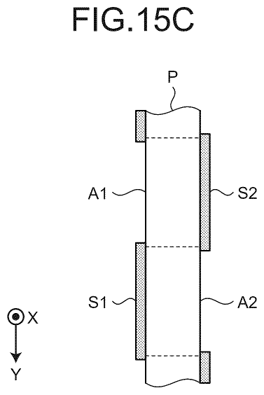

FIGS. 15A and 15B are enlarged views of the textual-information display areas according to a second modification of the third embodiment. FIG. 15C is a sectional arrow view taken along line A-A illustrated in FIGS. 15A and 15B. The same description as that in the first embodiment may be omitted.

In the configuration according to the second modification of the third embodiment, the first areas A1 are each provided correspondingly to one or more pixel rows in each of which the pixels Pix1 are arranged in the X direction (first direction). The second areas A2 are each provided correspondingly to one or more pixel rows in each of which the pixels Pix2 are arranged in the X direction (first direction). In other words, the first areas A1 and the second areas A2 each include one or more pixel rows arranged in the Y direction (second direction).

In the configuration according to the second modification of the third embodiment, the first areas A1 and the second areas A2 are provided so as to be alternately arranged in the Y direction (second direction). As a result, the first light-blocking pattern S1 and the second light-blocking pattern S2 each form a horizontal stripe-shaped light-blocking pattern per one or more pixel rows.

As illustrated in FIGS. 15A, 15B, and 15C, in the configuration according to the second modification of the third embodiment, the first light-blocking patterns S1 overlap the second light-blocking patterns S2 in predetermined areas including boundary lines between the first areas A1 and the second areas A2 indicated by dashed lines in plan view. In the same way as in the third embodiment, this configuration can reduce the light leakage in the second areas A2 when the first surface 7a of the display panel P is viewed from the one side. The light leakage in the first areas A1 can also be reduced when the second surface 7b of the display panel P is viewed from the other side.

### 4. Fourth Embodiment

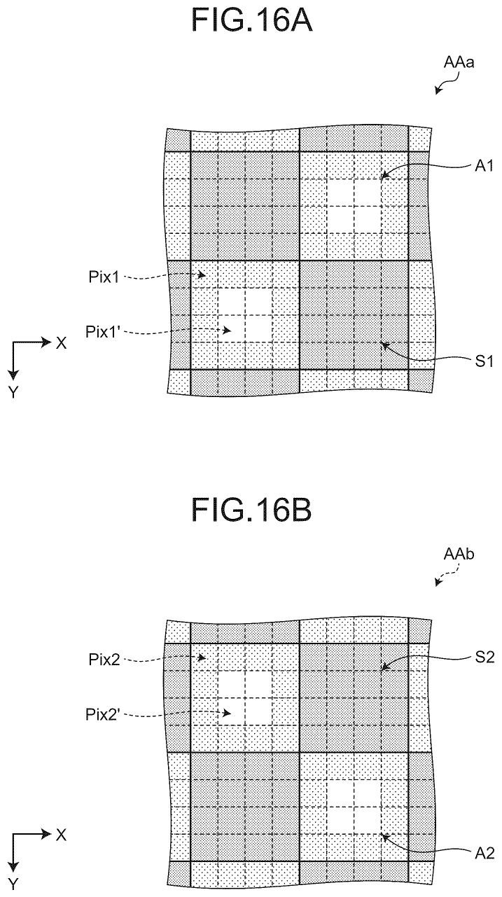

FIGS. 16A and 16B are enlarged views of the textual-information display areas according to a fourth embodiment of the present disclosure. The same description as that in the first embodiment may be omitted.

In the configuration according to the fourth embodiment, the first areas A1 are each provided correspondingly to more than one of the pixels Pix1. The second areas A2 are each provided correspondingly to more than one of the pixels Pix2.

In other words, the first areas A1 each include more than one of the pixels Pix1 in the X direction (first direction). The second areas A2 each include more than one of the pixels Pix2 in the X direction (first direction). This embodiment exemplifies an aspect in which the first areas A1 each include four of the pixels Pix1 in the X direction (first direction) and the second areas A2 each include four of the pixels Pix2 in the X direction (first direction).

The first areas A1 each include also more than one of the pixels Pix1 in the Y direction (second direction). The second areas A2 each include more than one of the pixels Pix2 in the Y direction (second direction). This embodiment exemplifies an aspect in which the first areas A1 each include four of the pixels Pix1 in the Y direction (second direction) and the second areas A2 each include four of the pixels Pix2 in the Y direction (second direction).

In the configuration according to the fourth embodiment, the first areas A1 and the second areas A2 are provided so as to be alternately arranged in the X direction (first direction). The first areas A1 and the second areas A2 are provided so as to be also alternately arranged in the Y direction (second direction). As a result, the first light-blocking pattern S1 and the second light-blocking pattern S2 each form a checkered light-blocking pattern on a plurality of (in this case, 4×4=16) pixels basis.

As illustrated in FIGS. 16A and 16B, in the configuration according to the fourth embodiment, the image processing circuit 70 performs the image processing so that the luminance of the pixel Pix1 in the first area A1 adjacent to the second area A2 is lower than that of a pixel Pix1′ in the first area A1 not adjacent to the second area A2. The image processing circuit 70 also performs the image processing so that the luminance of the pixel Pix2 in the second area A2 adjacent to the first area A1 is lower than that of a pixel Pix2′ in the second area A2 not adjacent to the first area A1. This configuration can reduce the light leakage in the second areas A2 when the first surface 7a of the display panel P is viewed from the one side. The light leakage in the first areas A1 can also be reduced when the second surface 7b of the display panel P is viewed from the other side.

### First Modification

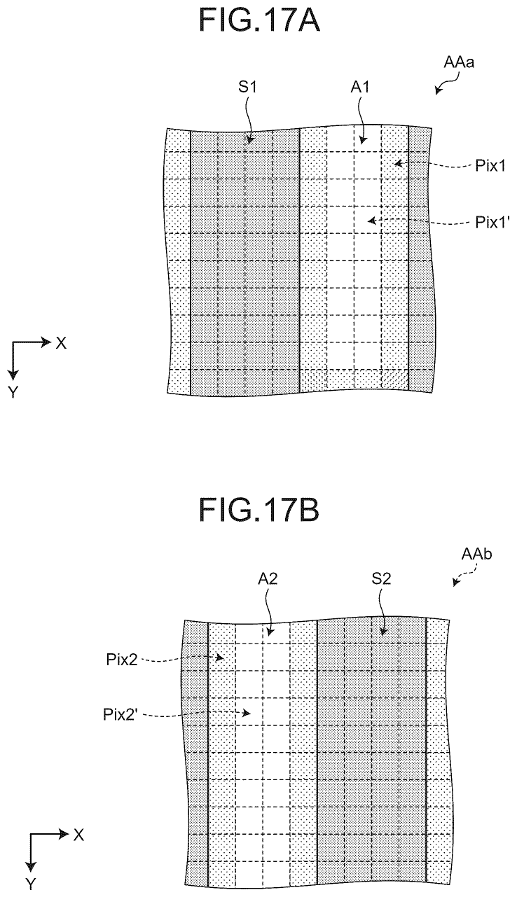

FIGS. 17A and 17B are enlarged views of the textual-information display areas according to a first modification of the fourth embodiment. The same description as that in the first embodiment may be omitted.

In the configuration according to the first modification of the fourth embodiment, the first areas A1 are each provided correspondingly to a plurality of pixel columns in each of which the pixels Pix1 are arranged in the Y direction (second direction). The second areas A2 are each provided correspondingly to a plurality of pixel columns in each of which the pixels Pix2 are arranged in the Y direction (second direction). In other words, the first areas A1 and the second areas A2 each include a plurality of pixel columns arranged in the X direction (first direction). This modification exemplifies an aspect in which the first areas A1 and the second areas A2 each include four pixel columns arranged in the X direction (first direction).

In the configuration according to the first modification of the fourth embodiment, the first area A1 and the second area A2 are provided so as to be alternately arranged in the X direction (first direction). As a result, the first light-blocking pattern S1 and the second light-blocking pattern S2 each form a vertical stripe-shaped light-blocking pattern on a plurality of (in this case, 4) pixel columns basis.

As illustrated in FIGS. 17A and 17B, in the configuration according to the first modification of the fourth embodiment, in the same way as in the fourth embodiment, the image processing circuit 70 performs the image processing so that the luminance of the pixel Pix1 in the first area A1 adjacent to the second area A2 is lower than that of the pixel Pix1′ in the first area A1 not adjacent to the second area A2. In the same way as in the fourth embodiment, the image processing circuit 70 also performs the image processing so that the luminance of the pixel Pix2 in the second area A2 adjacent to the first area A1 is lower than that of the pixel Pix2′ in the second area A2 not adjacent to the first area A1. In the same way as in the fourth embodiment, this configuration can reduce the light leakage in the second areas A2 when the first surface 7a of the display panel P is viewed from the one side. The light leakage in the first areas A1 can also be reduced when the second surface 7b of the display panel P is viewed from the other side.

### Second Modification

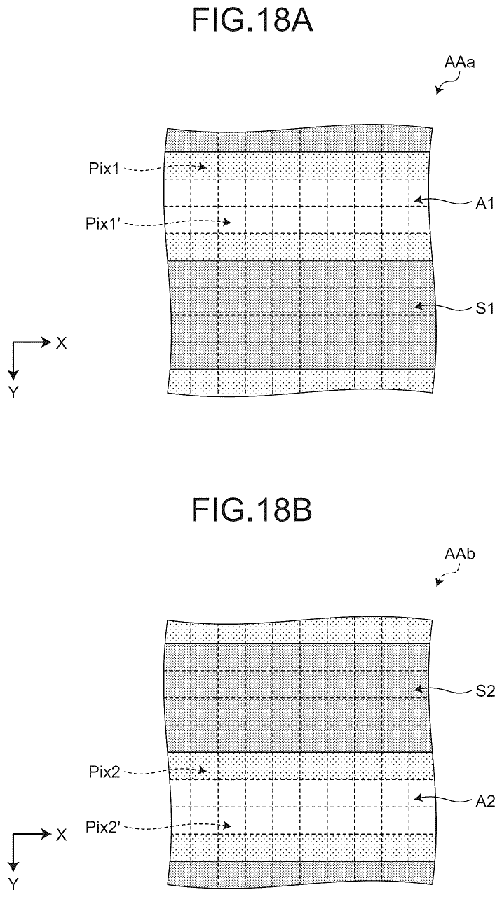

FIGS. 18A and 18B are enlarged views of the textual-information display areas according to a second modification of the fourth embodiment. The same description as that in the first embodiment may be omitted.

In the configuration according to the second modification of the fourth embodiment, the first areas A1 are each provided correspondingly to a plurality of pixel rows in each of which the pixels Pix1 are arranged in the X direction (first direction). The second areas A2 are each provided correspondingly to a plurality of pixel rows in each of which the pixels Pix2 are arranged in the X direction (first direction). In other words, the first areas A1 and the second areas A2 each include a plurality of pixel rows arranged in the Y direction (second direction). This modification exemplifies an aspect in which the first areas A1 and the second areas A2 each include four pixel rows arranged in the Y direction (second direction).

In the configuration according to the second modification of the fourth embodiment, the first areas A1 and the second areas A2 are provided so as to be alternately arranged in the Y direction (second direction). As a result, the first light-blocking pattern S1 and the second light-blocking pattern S2 each form a horizontal stripe-shaped light-blocking pattern on a plurality of (in this case, 4) pixel rows basis.

As illustrated in FIGS. 18A and 18B, in the configuration according to the second modification of the fourth embodiment, in the same way as in the fourth embodiment, the image processing circuit 70 performs the image processing so that the luminance of the pixel Pix1 in the first area A1 adjacent to the second area A2 is lower than that of the pixel Pix1′ in the first area A1 not adjacent to the second area A2. In the same way as in the fourth embodiment, the image processing circuit 70 also performs the image processing so that the luminance of the pixel Pix2 in the second area A2 adjacent to the first area A1 is lower than that of the pixel Pix2′ in the second area A2 not adjacent to the first area A1. In the same way as in the fourth embodiment, this configuration can reduce the light leakage in the second areas A2 when the first surface 7a of the display panel P is viewed from the one side. The light leakage in the first areas A1 can also be reduced when the second surface 7b of the display panel P is viewed from the other side.

In the embodiments and the modifications thereof described above, the transmissive liquid crystal display device that performs the display output using the FSC system has been described, but the display panel P is not limited to being configured as the liquid crystal display device using the FSC system. The display panel P may be, for example, a transmissive color liquid crystal display panel in which one pixel is composed of a first sub-pixel, a second sub-pixel, and a third sub-pixel. The first sub-pixel is a sub-pixel overlaid with a first color filter that transmits light in a first color (for example, red (R)). The second sub-pixel is a sub-pixel overlaid with a second color filter that transmits light in a second color (for example, green (G)). The third sub-pixel is a sub-pixel overlaid with a third color filter that transmits light in a third color (for example, blue (B)). In this case, the first area A1 and the second area A2 each include the first sub-pixel, the second sub-pixel, and the third sub-pixel as one unit. Alternatively, for example, the display panel P may be configured as a self-luminous organic electroluminescent (EL) display device.

While the preferred embodiments have been described above, the present disclosure is not limited to such embodiments. The content disclosed in the embodiments is merely an example, and can be variously modified within the scope not departing from the gist of the present disclosure. For example, any modifications appropriately made within the scope not departing from the gist of the present disclosure also naturally belong to the technical scope of the present invention.

What is claimed is:

1. A display device comprising a display panel that has a display area in which a plurality of pixels are arranged in a first direction and a second direction intersecting the first direction and is configured to allow a mirror image of an image viewed in plan view from one side of the display area to be viewed from another side, wherein
at least a partial area of the display area comprises:
a plurality of first areas each of which is visible from the one side and has a surface on the other side configured to be shielded from light; and
a plurality of second areas each of which is visible from the other side and has a surface on the one side configured to be shielded from light.

2. The display device according to claim 1, wherein the first areas and the second areas are alternately arranged in the first direction.

3. The display device according to claim 1, wherein the first areas and the second areas are alternately arranged in the second direction.

4. The display device according to claim 1, wherein
the first areas and the second areas are alternately arranged in the first direction, and
the first areas and the second areas are alternately arranged in the second direction.

5. The display device according to claim 2, wherein the first areas and the second areas each comprise one pixel in the first direction.

6. The display device according to claim 3, wherein the first areas and the second areas each comprise one pixel in the second direction.

7. The display device according to claim 4, wherein
the first areas and the second areas each comprise one pixel in the first direction, and
the first areas and the second areas each comprise one pixel in the second direction.

8. The display device according to claim 5, wherein, in plan view, light-blocking portions on the surfaces of the first areas on the other side overlap light-blocking portions on the surfaces of the second areas on the one side in predetermined areas including boundary lines between the first areas and the second areas.

9. The display device according to claim 6, wherein, in plan view, light-blocking portions on the surfaces of the first areas on the other side overlap light-blocking portions on the surfaces of the second areas on the one side in predetermined areas including boundary lines between the first areas and the second areas.

10. The display device according to claim 7, wherein, in plan view, light-blocking portions on the surfaces of the first areas on the other side overlap light-blocking portions on the surfaces of the second areas on the one side in predetermined areas including boundary lines between the first areas and the second areas.

11. The display device according to claim 2, wherein the first areas and the second areas each comprise a plurality of pixels in the first direction.

12. The display device according to claim 3, wherein the first areas and the second areas each comprise a plurality of pixels in the second direction.

13. The display device according to claim 4, wherein
the first areas and the second areas each comprise a plurality of pixels in the first direction, and
the first areas and the second areas each comprise a plurality of pixels in the second direction.

14. The display device according to claim 11, wherein, in plan view, light-blocking portions on the surfaces of the first areas on the other side overlap light-blocking portions on the surfaces of the second areas on the one side in predetermined areas including boundary lines between the first areas and the second areas.

15. The display device according to claim 12, wherein, in plan view, light-blocking portions on the surfaces of the first areas on the other side overlap light-blocking portions on the surfaces of the second areas on the one side in predetermined areas including boundary lines between the first areas and the second areas.

16. The display device according to claim 13, wherein, in plan view, light-blocking portions on the surfaces of the first areas on the other side overlap light-blocking portions on the surfaces of the second areas on the one side in predetermined areas including boundary lines between the first areas and the second areas.

17. The display device according to claim 11, wherein
luminance of the pixels in the first areas adjacent to the second areas is lower than luminance of the pixels in the first areas not adjacent to the second areas, and
luminance of the pixels in the second areas adjacent to the first areas is lower than luminance of the pixels in the second areas not adjacent to the first areas.

18. The display device according to claim 12, wherein
luminance of the pixels in the first areas adjacent to the second areas is lower than luminance of the pixels in the first areas not adjacent to the second areas, and
luminance of the pixels in the second areas adjacent to the first areas is lower than luminance of the pixels in the second areas not adjacent to the first areas.

19. The display device according to claim 13, wherein
luminance of the pixels in the first areas adjacent to the second areas is lower than luminance of the pixels in the first areas not adjacent to the second areas, and
luminance of the pixels in the second areas adjacent to the first areas is lower than luminance of the pixels in the second areas not adjacent to the first areas.

20. The display device according to claim 14, wherein
luminance of the pixels in the first areas adjacent to the second areas is lower than luminance of the pixels in the first areas not adjacent to the second areas, and
luminance of the pixels in the second areas adjacent to the first areas is lower than luminance of the pixels in the second areas not adjacent to the first areas.
